(19) United States
(12) Patent Application Publication
(10) Pub. No.: US 2026/0012149 A1
(43) Pub. Date: Jan. 8, 2026

(54) HARMONIC PROCESSING CIRCUIT AND AMPLIFIER

(71) Applicant: Fujitsu Limited, Kawasaki-shi (JP)

(72) Inventor: Yoichi KAMADA, Machida (JP)

(73) Assignee: Fujitsu Limited, Kawasaki-shi (JP)

(21) Appl. No.: 19/257,331

(22) Filed: Jul. 1, 2025

(30) Foreign Application Priority Data
Jul. 8, 2024 (JP) 2024-109610

(51) Int. Cl. H03F 3/60; H03F 1/56

(52) U.S. Cl. CPC H03F 3/601; H03F 1/56

(57) ABSTRACT

A harmonic processing circuit includes a transmission line for transmitting the fundamental wave, a first wire connected to the transmission line, a second wire provided parallel to and apart from the first wire, and a dielectric film interposed between the first wire and the second wire. The first wire has a first end connected to the transmission line and a second end opened. The length between the first end and the second end of the first wire is set to ¼ wavelength of a predetermined harmonic with respect to the fundamental wave. The second wire has both first and second ends opened. The length between the first end and the second end of the second wire is set to ¼ wavelength of the predetermined harmonic.

### CROSS-REFERENCE TO RELATED APPLICATION

This application is based upon and claims the benefit of priority of the prior Japanese Patent Application No. 2024-109610, filed on Jul. 8, 2024, the entire contents of which are incorporated herein by reference.

### FIELD

The embodiments discussed herein relate to a harmonic processing circuit and an amplifier.

### BACKGROUND

There is a known harmonic processing circuit for shorting the second harmonic using a pair of transmission lines having the same length as ⅛ wavelength of the fundamental wave, and an amplifier using the harmonic processing circuit is also known (see, for example, Japanese Laid-open Patent Publication No. 2018-142827). For example, a technique is known in which a first transmission line having a first end connected to an amplifying element and a second end opened is placed parallel to a second transmission line having both ends opened with a gap therebetween (see, for example, Japanese Laid-open Patent Publication No. 2018-142827).

### SUMMARY

According to one aspect, there is provided a harmonic processing circuit including: a transmission line configured to transmit a fundamental wave; a first wire configured to have a first end connected to the transmission line and a second end opened, a length between the first end and the second end being ¼ wavelength of a predetermined harmonic with respect to the fundamental wave; a second wire configured to be parallel to and apart from the first wire, and have both ends opened, a length between the both ends being ¼ wavelength of the predetermined harmonic; and a first dielectric film configured to be interposed between the first wire and the second wire.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of an amplifier;

FIG. 2 illustrates an example of an amplifier including a harmonic processing circuit according to a first embodiment;

FIGS. 3A and 3B illustrate an example of the harmonic processing circuit according to the first embodiment;

FIG. 4 illustrates a first modification of the amplifier including the harmonic processing circuit according to the first embodiment;

FIG. 5 illustrates a second modification of the amplifier including the harmonic processing circuit according to the first embodiment;

FIGS. 6A and 6B illustrate a first configuration example of a harmonic processing circuit according to a second embodiment;

FIG. 7 further illustrates the first configuration example of the harmonic processing circuit according to the second embodiment;

FIGS. 8A and 8B illustrate a second configuration example of the harmonic processing circuit according to the second embodiment;

FIGS. 9A and 9B further illustrate the second configuration example of the harmonic processing circuit according to the second embodiment;

FIGS. 10A and 10B illustrate a third configuration example of the harmonic processing circuit according to the second embodiment;

FIG. 11 further illustrates the third configuration example of the harmonic processing circuit according to the second embodiment;

FIG. 12 illustrates a configuration example of an amplifier according to a third embodiment; and

FIGS. 13A and 13B illustrate examples of simulation results of the amplifier according to the third embodiment.

### DESCRIPTION OF EMBODIMENTS

An amplifier using a harmonic processing circuit may suffer deterioration in characteristics, such as a reduction in the frequency bandwidth of a signal and a decrease in power added efficiency (PAE) caused by loss, if the performance of the harmonic processing circuit is not sufficient.

As an example of a transistor capable of high-power operation at high frequencies, a transistor using a nitride semiconductor such as gallium nitride (GaN), for example, a high electron mobility transistor (HEMT), is known. A technique of using the aforementioned transistor in an amplifier is known.

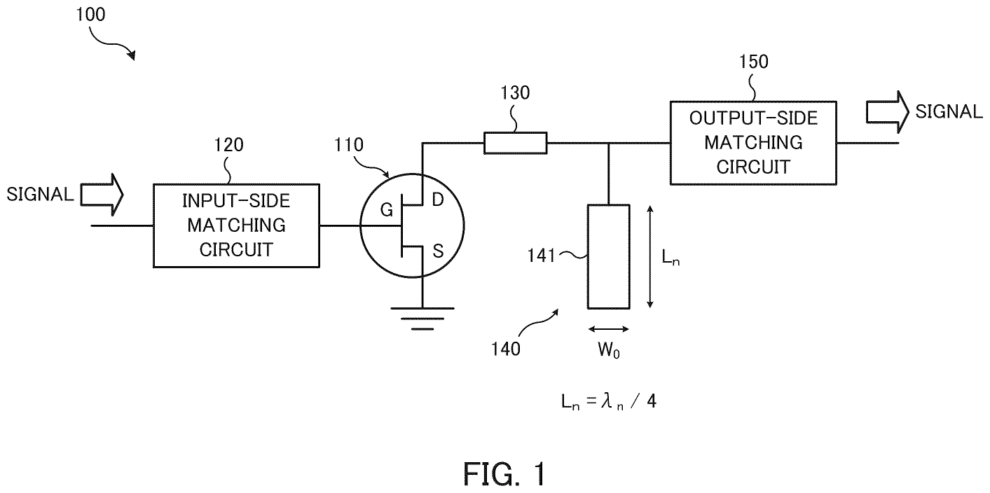

FIG. 1 illustrates an example of an amplifier.

FIG. 1 schematically illustrates an equivalent circuit of the example of the amplifier.

An amplifier 100 illustrated in FIG. 1 includes a transistor 110 which is an amplifying element. For example, a HEMT transistor using a nitride semiconductor, such as GaN, is used as the transistor 110.

An input-side matching circuit 120 is connected to an input side of the transistor 110, that is, a gate G side. The input-side matching circuit 120 is provided to match impedance on a power supply side connected to the gate G of the transistor 110 and impedance on the input side of the transistor 110. For example, the impedance is set at or near 50 Ω.

A transmission line 130, a harmonic processing circuit 140, and an output-side matching circuit 150 are connected to an output side, that is, a drain D side of the transistor 110. The harmonic processing circuit 140 is connected to the transmission line 130 that connects the drain D of the transistor 110 and the output-side matching circuit 150. The output-side matching circuit 150 is provided to match impedance on a load side connected to the drain D of the transistor 110 and impedance on the output side of the transistor 110 including the transmission line 130 and the harmonic processing circuit 140. For example, the impedance is set at or near 50 Q.

The source S of the transistor 110 is grounded.

Next described is the harmonic processing circuit 140 of the amplifier 100 having the above configuration.

In the amplifier 100, a high-frequency signal is input to the transistor 110, and an amplified high-frequency signal is output from the transistor 110. The high frequency at which the transistor 110 operates and the frequency thereof are also referred to as a fundamental wave and an operating frequency, respectively. In the amplifier 100, the harmonic processing circuit 140 is connected in order to suppress power consumption and increase power efficiency.

The harmonic processing circuit 140 shorts an n-th harmonic ((n-1)-th overtone), which is a component of a frequency fₙ that is n times (n is an integer of 2 or more) a frequency f₁ (operating frequency) of the fundamental wave.

For example, a so-called open stub 141 is used as the harmonic processing circuit 140. The open stub 141 is an open-circuited stub whose first end is connected to the transmission line 130 and a second end (tip) thereof is opened. The harmonic processing circuit 140 may include the transmission line 130 or a part thereof. The open stub 141 is connected to the transmission line 130. The transmission line 130 is provided for transmitting the fundamental wave. The length of the transmission line 130 is set to, for example, λ₁/4, where λ₁ is the wavelength of the frequency f₁ of the fundamental wave. The length of the open stub 141 is set to λₙ/4, where λₙ is the wavelength of the frequency fₙ of the n-th harmonic.

The relationship between the frequency f₁ of the fundamental wave and the frequency fₙ of the n-th harmonic is expressed by Equation (1) below. The relationship between the wavelength λ₁ of the fundamental wave and the wavelength λₙ of the n-th harmonic is expressed by Equation (2) below.

$${f}_{n} = {f}_{1} \times n \qquad ( 1 )$$

$${λ}_{n} = {λ}_{1} / n \qquad ( 2 )$$

The open stub 141 is a stub for forming a short-circuit point for the frequency fₙ of the n-th harmonic.

In general, input impedance Zᵢₙ of an open stub is expressed by Equation (3) below.

$${Z}_{i n} = - {jZ}_{0} cot ( β \times L ) \qquad ( 3 )$$

In Equation (3), L is the length of the open stub. β is a phase constant, and is a phase angle that changes while a signal wave travels through the open stub by a unit length. For a wavelength λ of the signal wave, β=2π/λ. Note that β×L represents the electrical length of the open stub. Z₀ is the characteristic impedance (width) of the open stub.

When L=λ/4 and β=2π/λ, Equation (3) becomes Equation (3a) below, and the input impedance Zᵢₙ of the open stub is 0, that is, the open stub is short-circuited.

$${Z}_{i n} = - {jZ}_{0} cot ( ( 2 Π / {λ}_{n} ) \times ( {λ}_{n} / 4 ) ) = 0 \qquad ( 3 a )$$

Here, in the harmonic processing circuit 140, when the n-th harmonic of the frequency fₙ and the wavelength λₙ is short-circuited, the input impedance Zᵢₙ of the open stub 141 is expressed by Equation (3b) below from Equation (3a).

$${Z}_{i n} = - {jZ}_{0} cot ( ( 2 Π / {λ}_{n} ) \times ( {λ}_{n} / 4 ) ) = 0 \qquad ( 3 b )$$

Therefore, when the length of the open stub 141 for shorting the n-th harmonic is Lₙ, the length Lₙ is expressed by Equation (4) below.

$$L = {λ}_{n} / 4 = ( {λ}_{1} / n ) / 4 = {λ}_{1} / ( 4 \times n ) \qquad ( 4 )$$

Therefore, when the length Lₙ of the open stub 141 is set to ¼ of the wavelength λₙ of the n-th harmonic, that is, 1/(4×n) of the wavelength λ₁ of the fundamental wave, the input impedance Zᵢₙ of the open stub 141 becomes 0 with respect to the frequency fₙ of the n-th harmonic, and a short circuit occurs. For example, in the case of shorting the first overtone, i.e., the second harmonic, with the frequency f₂ and the wavelength λ₂, a length L₂ of the open stub 141 may be set to ¼ of the wavelength λ₂ of the second harmonic, or ⅛ of the wavelength λ₁ of the fundamental wave.

In the harmonic processing circuit 140, the length Lₙ of the open stub 141 is set based on the (n−1)-th overtone (n-th harmonic) to be processed (shorted).

As described above, the harmonic processing circuit 140 is provided to suppress the power consumption of the amplifier 100 to thereby increase the power efficiency. In the harmonic processing circuit 140, the length L, of the open stub 141 formed by a single wire is set based on the n-th harmonic to be shorted. In the harmonic processing circuit 140, a width W₀ of the open stub 141 formed by a single wire is set based on the characteristic impedance.

However, due to the influence of stray capacitance caused by providing the harmonic processing circuit 140, the amplifier 100 may suffer deterioration in characteristics, such as a reduction in the frequency bandwidth of a signal and a decrease in the PAE caused by loss (reflection loss or the like).

For example, the open stub 141 of the harmonic processing circuit 140 is realized in the form of a microstrip line or the like together with the transmission line 130 and possibly also a transmission line of the output-side matching circuit 150. Therefore, stray capacitance may be generated between the open stub 141 and peripheral conductors, for example, the transmission line 130 and conductor layers such as microstrip lines. As in the case of the harmonic processing circuit 140, the length Lₙ and the width W₀, or just the width W₀, of the open stub 141 made up of a single wire are relatively large, which makes the area thereof relatively large. As a result, the likelihood of stray capacitance occurring may increase. Even if the length Lₙ of the open stub 141 is set based on the n-th harmonic, the stray capacitance due to the harmonic processing circuit 140 affects shorting, reflection, phase, and like of the n-th harmonic, and may cause deterioration in the characteristics of the amplifier 100, such as a reduction in the frequency bandwidth of a signal and a decrease in the PAE caused by loss.

Insufficient performance of the harmonic processing circuit 140, such as introducing stray capacitance, may prevent the amplifier 100 from having a wide bandwidth and high power efficiency.

In view of the above points, a high-performance harmonic processing circuit and an amplifier having the harmonic processing circuit are realized by adopting a configuration described below as embodiments.

### (a) First Embodiment

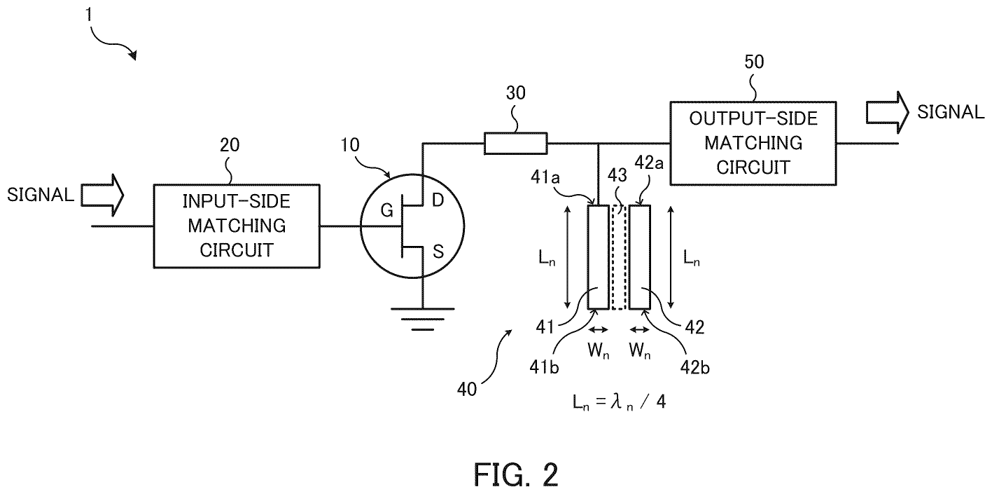

FIG. 2 illustrates an example of an amplifier including a harmonic processing circuit according to a first embodiment. FIG. 2 schematically illustrates an equivalent circuit of the example of the amplifier.

An amplifier 1 depicted in FIG. 2 includes a transistor 10 as an amplifying element. A transistor, for example, a HEMT using a nitride semiconductor, such as GaN, is used as the transistor 10.

An input-side matching circuit 20 is connected to an input side of the transistor 10, that is, a gate G side. The input-side matching circuit 20 is provided to match impedance on a power supply side connected to the gate G of the transistor 10 and impedance on the input side of the transistor 10. For example, the impedance is set at or near 50 Ω.

A transmission line 30, a harmonic processing circuit 40, and an output-side matching circuit 50 are connected to an output side, that is, a drain D side of the transistor 10. The harmonic processing circuit 40 is connected to the transmission line 30 that connects the drain D of the transistor 10 and the output-side matching circuit 50. The harmonic processing circuit 40 may include the transmission line 30 or a part thereof, or may further include a transmission line of the output-side matching circuit 50 or a part thereof. The output-side matching circuit 50 is provided to match impedance on a load side connected to the drain D of the transistor 10 and impedance on the output side of the transistor 10 including the transmission line 30 and the harmonic processing circuit 40. For example, the impedance is set at or near 50 Q.

The source S of the transistor 10 is grounded.

Next described is the harmonic processing circuit 40 of the amplifier 1 having the above configuration.

The harmonic processing circuit 40 of the amplifier 1 includes two wires 41 and 42. For example, the wires 41 and 42 are realized in the form of a microstrip line or the like together with the transmission line 30 and possibly also the transmission line of the output-side matching circuit 50.

A first end 41a of the wire 41 is connected to the transmission line 30, and a second end 41b is opened. The wire 41 is a so-called open-circuited stub. The length Lₙ between the first end 41a and the second end 41b of the wire 41 is set to ¼ wavelength of a predetermined harmonic with respect to the fundamental wave. That is, the length Lₙ of the wire 41 is set to ¼ of the wavelength Δₙ of the (n-1)-th overtone (n-th harmonic), which is a component of the frequency fₙ that is n times (n is an integer of 2 or more) the frequency f₁ (operating frequency) of the fundamental wave. A width Wₙ of the wire 41 is set to a width smaller than the width W₀ of the single open stub 141 of the harmonic processing circuit 140 in the amplifier 100 described above with reference to FIG. 1. For example, the width Wₙ of the wire 41 is set to half the width W₀.

The wire 42 is provided parallel to the wire 41 and separated from the wire 41. Both ends of the wire 42, that is, a first end 42a and a second end 42b are opened. The length between the first end 42a and the second end 42b of the wire 42 is the same as that of the wire 41. That is, the length between the first end 42a and the second end 42b of the wire 42 is set to ¼ of the wavelength of a predetermined harmonic with respect to the fundamental wave, namely, ¼ of the wavelength λₙ of the n-th harmonic, which is a component of the frequency fₙ that is n times the frequency f₁ of the fundamental wave. The width Wₙ of the wire 42 is set to a width smaller than the width W₀ of the single open stub 141 of the harmonic processing circuit 140 in the amplifier 100 described above with reference to FIG. 1. For example, the width Wₙ of the wire 42 is set to half the width W₀.

The wire 42 is provided in such a manner that a dielectric film 43 is interposed between the wires 42 and 41. For the dielectric film 43 interposed between the wires 42 and 41, various resins, or materials such as various oxides, nitrides, and oxynitrides are used. The wire 42 having the dielectric film 43 interposed between the wires 42 and 41 may be capacitively coupled to the wire 41 via the dielectric film 43 for a predetermined harmonic. The interval between the wires 41 and 42 and the materials used for the dielectric film 43 provided therein are set based on, for example, the frequency f₁ of the fundamental wave and the frequency fₙ of the n-th harmonic based on the frequency f₁.

The transmission line 30 is for transmitting the fundamental wave. The length of the transmission line 30 is set to, for example, ¼ of the wavelength λ₁ of the fundamental wave.

In FIG. 2, for convenience of describing the circuit configuration of the amplifier 1, the wires 41 and 42 and the dielectric film 43 interposed therebetween are illustrated as the harmonic processing circuit 40. Note however that, when the harmonic processing circuit 40 is realized in the form of a microstrip line or the like, the wire 41 is formed continuously with the transmission line 30 so as to be connected to the transmission line 30 at the first end 41a. The wire 41 may further be formed continuously with the transmission line of the output-side matching circuit 50. The harmonic processing circuit 40 may include, as its components, the transmission line 30 or a part thereof, or may further include the transmission line of the output-side matching circuit 50 or a part thereof, in addition to the wires 41 and 42 and the dielectric film 43 interposed between the wires 41 and 42.

The wire 41 of the harmonic processing circuit 40 is also referred to as a “first wire”, the wire 42 is also referred to as a “second wire”, and the dielectric film 43 is also referred to as a “first dielectric film”.

In the amplifier 1, a high-frequency signal is input to the transistor 10, and an amplified high-frequency signal is output from the transistor 10. In the amplifier 1, the harmonic processing circuit 40 for shorting a predetermined n-th harmonic, such as the second harmonic, with respect to the fundamental wave is connected in order to suppress power consumption and increase power efficiency.

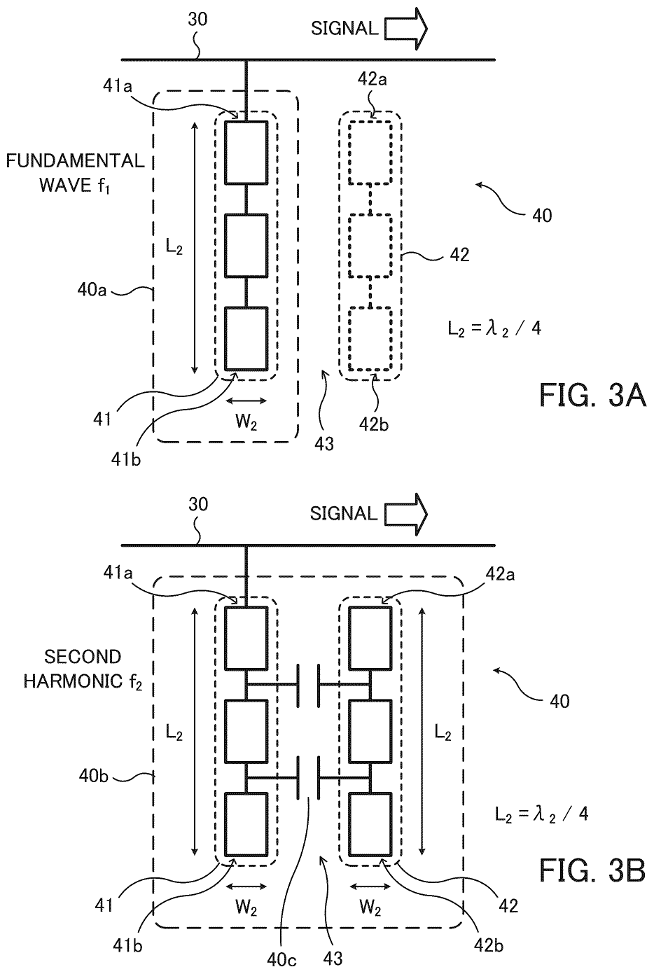

FIGS. 3A and 3B illustrate an example of the harmonic processing circuit according to the first embodiment. FIG. 3A illustrates a function of the harmonic processing circuit for the fundamental wave. FIG. 3B illustrates a function of the harmonic processing circuit for the second harmonic. FIGS. 3A and 3B schematically depict equivalent circuits of the harmonic processing circuit and a transmission line connected thereto.

Here, as an example, a case is described in which a second harmonic with a frequency f₂ twice the frequency f₁ of the fundamental wave and a wavelength λ₂ is a short circuit target. In this case, each of the wires 41 and 42 of the harmonic processing circuit 40, which are arranged parallel to and apart from each other via the dielectric film 43, has the length L₂ set to ¼ wavelength of the second harmonic, that is, λ₂/4.

In the harmonic processing circuit 40, the wire 41 whose first end 41a is connected to the transmission line 30 and the wire 42 arranged parallel to and apart from the wire 41 have the length L₂, which is set to ¼ wavelength of the second harmonic (> 2/4), in other words, ⅛ wavelength of the fundamental wave (>⅛). Accordingly, for the fundamental wave with the frequency f₁, as depicted in FIG. 3A, the capacitive coupling between the wires 41 and 42 does not occur or becomes very small. That is, with respect to the fundamental wave, of the two wires 41 and 42 of the harmonic processing circuit 40, only the wire 41 (a range 40a in FIG. 3A) connected to the transmission line 30 is visible and effective. The harmonic processing circuit 40 may be regarded as the single wire 41 with the second end 41b opened and having a length of ⅛ wavelength of the fundamental wave, and functions as a capacitor for the fundamental wave.

On the other hand, for the second harmonic with the frequency f₂ (=f₁×2), since the length L₂ of the wires 41 and 42 is set to ¼ wavelength of the second harmonic (λ₂/4), the wires 41 and 42 are capacitively coupled as illustrated in FIG. 3B. That is, for the second harmonic, both the wire 41 and the wire 42 capacitively coupled thereto (a range 40b in FIG. 3B) of the harmonic processing circuit 40 are visible and effective. Note that, in FIG. 3B, the capacitive coupling between the wires 41 and 42 is represented by connecting the wires 41 and 42 by capacitors 40c. In the harmonic processing circuit 40, for the second harmonic, the wires 41 and 42 may be regarded as a single capacitively coupled open-circuited stub, i.e., an open stub. The second harmonic is shorted by the single open stub formed by the capacitively coupled wires 41 and 42.

As described above, for the fundamental wave, the harmonic processing circuit 40 is regarded as the single wire 41 and functions as a capacitor. For the second harmonic, on the other hand, the harmonic processing circuit 40 function as a single open stub by capacitive coupling the two wires 41 and 42. As a result, the second harmonic is shorted, and the influence of the second harmonic on the fundamental wave transmitted from the transmission line 30 to the output-side matching circuit 50 is suppressed.

In the harmonic processing circuit 40, the length L₂ of each of the two wires 41 and 42 is set to λ₂/4, and the width W₂ is set to be less than the width W₀ of the single open stub 141 of the harmonic processing circuit 140 described in FIG. 1 (for example, half of the width W₀). Therefore, in the harmonic processing circuit 40, when the wire 41 is used for the fundamental wave, the area of the wire 41 is smaller than the area of the open stub 141. As a result, in transmission of the fundamental wave, the harmonic processing circuit 40 is able to reduce stray capacitance and therefore suppress loss (reflection loss or the like) caused by stray capacitance.

According to the above configuration, it is possible to realize the harmonic processing circuit 40 with high performance, capable of suppressing the influence of the second harmonic on the fundamental wave and further reducing stray capacitance and loss in the transmission of the fundamental wave. Furthermore, by employing the above high-performance harmonic processing circuit 40, it is possible to realize the amplifier 1 with high performance, capable of suppressing a reduction in the frequency bandwidth and a decrease in the PAE caused by loss.

The case where the second harmonic is targeted has been described here; however, also in the case where a different n-th harmonic is targeted, the dimensions and the like of the wires 41 and 42 may be set according to the example above.

For example, when the third harmonic is targeted, a length L₃ of each of the wires 41 and 42 is set to ¼ wavelength of the third harmonic (λ₃/4), that is, 1/12 wavelength of the fundamental wave (λ₁/12). A width W₃ of the wires 41 and 42 is set to be less than the width W₀ of the single open stub 141 of the harmonic processing circuit 140 described in FIG. 1 (for example, half of the width W₀).

For example, when the fourth harmonic is targeted, a length L₄ of each of the wires 41 and 42 is set to ¼ wavelength of the fourth harmonic (λ₄/4), that is, 1/16 wavelength of the fundamental wave (λ₁/16). A width W₄ of the wires 41 and 42 is set to be less than the width W₀ of the single open stub 141 of the harmonic processing circuit 140 described in FIG. 1 (for example, half of the width W₀).

Also for the fifth harmonic, the sixth harmonic, and so on, the dimensions and the like of the wires 41 and 42 are set according to the above-described examples.

The wires 41 and 42 set to predetermined dimensions based on an n-th harmonic to be shorted are arranged parallel to and apart from each other with the predetermined dielectric film 43 interposed therebetween. Herewith, it is possible to realize the harmonic processing circuit 40 which functions as the single wire 41 for the fundamental wave and shorts the n-th harmonic of the short circuit target by the two capacitively coupled wires 41 and 42.

In the harmonic processing circuit 40, the dielectric film 43 is interposed between the wires 41 and 42. Various dielectric materials, that is, dielectric materials having various relative permittivity values may be used for the dielectric film 43. Therefore, in the harmonic processing circuit 40, it is possible to accurately adjust the capacitance value between the wires 41 and 42 to an appropriate value compared to a case where a gap (void space or air gap) is formed between the wires 41 and 42. That is, in the harmonic processing circuit 40, in addition to the interval between the wires 41 and 42, the capacitance value between the wires 41 and 42 may also be adjusted by selecting the type of the dielectric film 43 interposed therebetween. Therefore, in the harmonic processing circuit 40, the capacitance value between the wires 41 and 42 is adjusted by more parameters than in a case where a gap is provided between the wires 41 and 42. As a result, the capacitance value is accurately adjusted to an appropriate value.

FIG. 2 depicts an example in which one harmonic processing circuit 40 for shorting a predetermined n-th harmonic (for example, the second harmonic) is provided. However, the number of harmonic processing circuits 40 is not limited thereto.

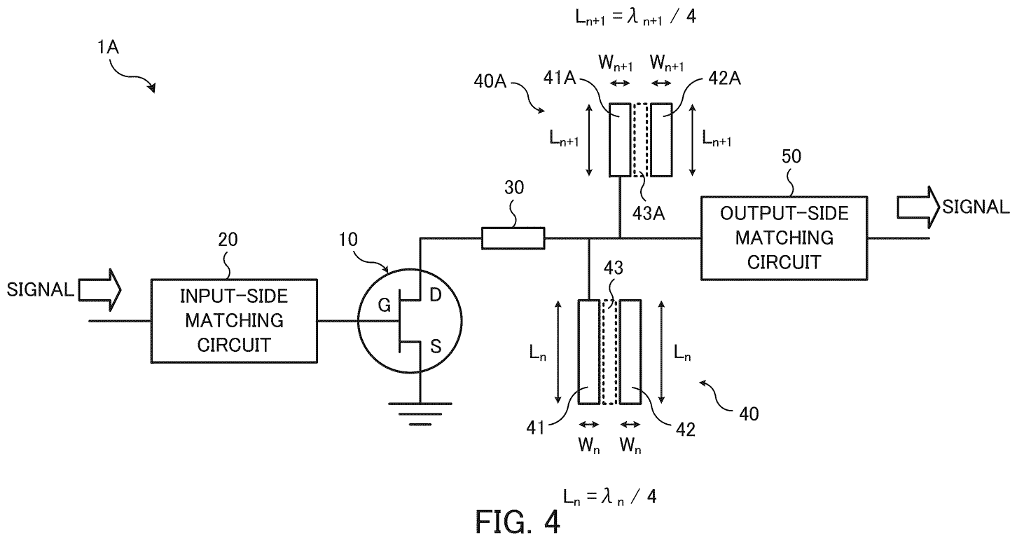

FIG. 4 illustrates a first modification of the amplifier including the harmonic processing circuit according to the first embodiment. FIG. 4 schematically illustrates an equivalent circuit of an example of the amplifier.

An amplifier 1A illustrated in FIG. 4 has a configuration in which a harmonic processing circuit 40A for shorting an (n+1)-th harmonic is provided in addition to the harmonic processing circuit 40 for shorting the n-th harmonic. The amplifier 1A is different from the amplifier 1 illustrated in FIG. 2 in that the amplifier 1A has the above configuration.

For each of the wires 41 and 42 of the harmonic processing circuit 40, the length Lₙ is set to ¼ of the wavelength λₙ of the n-th harmonic, and the width Wₙ is set to be less than the width W₀ of the single open stub 141 (FIG. 1) (for example, half of the width W₀). The dielectric film 43 is provided between the wires 41 and 42.

For each of wires 41A and 42A of the harmonic processing circuit 40A, a length Lₙ₊₁ is set to ¼ of a wavelength Anti of the (n+1)-th harmonic, and a width Wₙ₊₁ is set to be less than the width W₀ of the single open stub 141 (FIG. 1) (for example, half of the width W₀). The wire 41A is an open stub in which a first end is connected to the transmission line 30 and a second end is opened. The wire 42A is arranged parallel to and apart from the wire 41A. A dielectric film 43A is provided between the wires 41A and 42A.

The wire 41A of the harmonic processing circuit 40A is also referred to as the “first wire”, the wire 42A is also referred to as the “second wire”, and the dielectric film 43A is also referred to as the “first dielectric film”.

For example, the harmonic processing circuit 40 may be provided for shorting the second harmonic, and the harmonic processing circuit 40A may be provided for shorting the third harmonic. As in the amplifier 1A, the harmonic processing circuits 40 and 40A for shorting different harmonics may be connected in parallel to the transmission line 30.

In the amplifier 1A, the harmonic processing circuit 40 functions as the single wire 41 for the fundamental wave, and shorts the n-th harmonic of the short circuit target by the two wires 41 and 42 that are capacitively coupled. The harmonic processing circuit 40A functions as the single wire 41A for the fundamental wave, and shorts the (n+1)-th harmonic of the short circuit target by the two wires 41A and 42A that are capacitively coupled.

According to the amplifier 1A, by the harmonic processing circuits 40 and 40A, it is possible to suppress the influence of both the n-th harmonic and the (n+1)-th harmonic on the fundamental wave and further reduce stray capacitance and loss in the transmission of the fundamental wave. In this manner, it is possible to realize the amplifier 1A capable of further suppressing a reduction in the frequency bandwidth and a decrease in the PAE caused by loss.

According to the example of the amplifier 1A, it is also possible to realize an amplifier further provided with harmonic processing circuits for shorting harmonics such as an (n+2)-th harmonic and an (n+3)-th harmonic.

FIG. 2 depicts an example in which the harmonic processing circuit 40 is provided on the output side of the transistor 10; however, a harmonic processing circuit may be provided on the input side of the transistor 10.

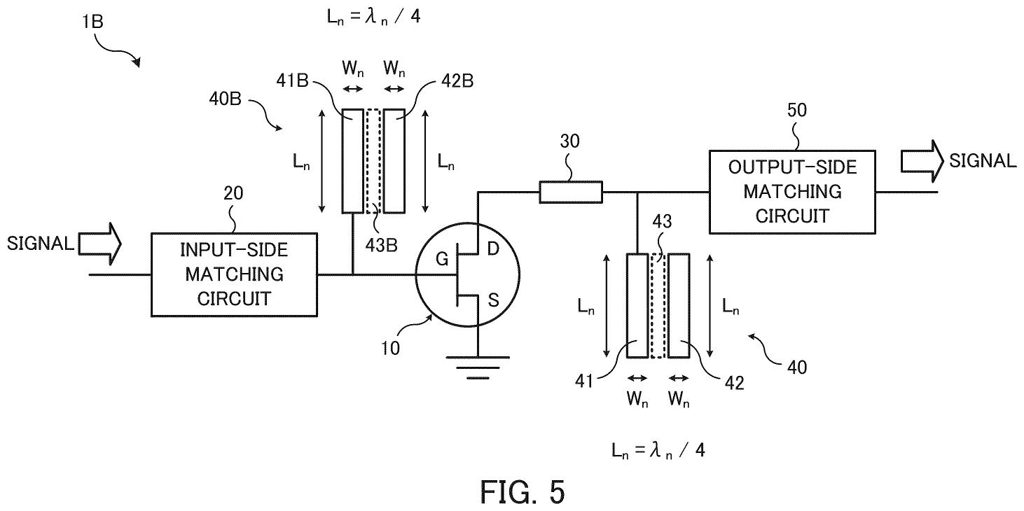

FIG. 5 illustrates a second modification of the amplifier including the harmonic processing circuit according to the first embodiment. FIG. 5 schematically illustrates an equivalent circuit of an example of the amplifier.

An amplifier 1B illustrated in FIG. 5 has a configuration in which the harmonic processing circuit 40 for shorting the n-th harmonic is provided on the drain D side, which is the output side of the transistor 10, and a harmonic processing circuit 40B for shorting the n-th harmonic is also provided on the gate G side, which is the input side of the transistor 10. The amplifier 1B is different from the amplifier 1 illustrated in FIG. 2 in that the amplifier 1B has the above configuration.

For each of the wires 41 and 42 of the harmonic processing circuit 40 on the output side, the length Lₙ is set to ¼ of the wavelength λₙ of the n-th harmonic, and the width Wₙ is set to be less than the width W₀ of the single open stub 141 (FIG. 1) (for example, half of the width W₀). The dielectric film 43 is provided between the wires 41 and 42.

The input-side harmonic processing circuit 40B may have, for example, the same configuration as that of the output-side harmonic processing circuit 40. For example, for each of wires 41B and 42B of the harmonic processing circuit 40B, the length Lₙ is set to ¼ of the wavelength λₙ of the n-th harmonic, and the width Wₙ is set to be less than the width W₀ of the single open stub 141 (FIG. 1) (for example, half of the width W₀). The wire 41B is an open stub in which a first end is connected to a transmission line of the input-side matching circuit 20 or a transmission line connected thereto and a second end is opened. The wire 42B is arranged parallel to and apart from the wire 41B. A dielectric film 43B is provided between the wires 41B and 42B.

The wire 41B of the harmonic processing circuit 40B is also referred to as the “first wire”, the wire 42B is also referred to as the “second wire”, and the dielectric film 43B is also referred to as the “first dielectric film”.

In the amplifier 1B, the same effect as that of the amplifier 1 is obtained on the output side of the transistor 10. According to the amplifier 1B, it is also possible to suppress the influence of the n-th harmonic on the fundamental wave on the input side of the transistor 10 and further reduce stray capacitance and loss in the transmission of the fundamental wave. In this manner, it is possible to realize the amplifier 1B capable of further suppressing a reduction in the frequency bandwidth and a decrease in the PAE caused by loss.

Note that the harmonic processing circuit 40B on the input side of the transistor 10 of the amplifier 1B may be provided to short a harmonic (the n+1 harmonic or the like) different from the harmonic (the n harmonic or the like) of the short circuit target on the output side.

Furthermore, on the output side or the input side of the transistor 10 of the amplifier 1B, a plurality of harmonic processing circuits for shorting different types of harmonics may be provided according to the example of the amplifier 1A depicted in FIG. 4.

The transistor 10 of the amplifiers 1, 1A, and 1B described above is not limited to a HEMT transistor using a nitride semiconductor, such as GaN, and various transistors functioning as an amplifying element may be applied.

### (b) Second Embodiment

Here, configuration examples (first to third configuration examples) of the above harmonic processing circuit 40 and the like are described as a second embodiment.

### First Configuration Example

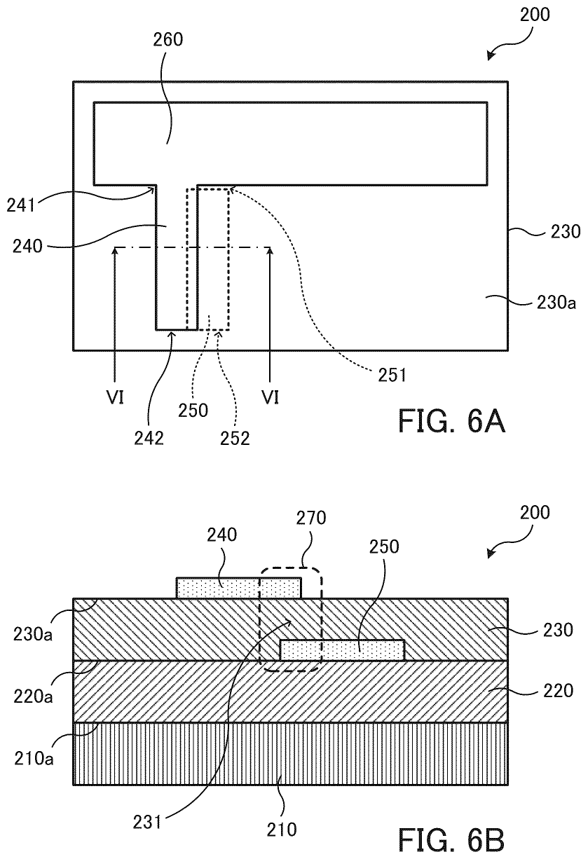

FIGS. 6A and 6B illustrate the first configuration example of the harmonic processing circuit according to the second embodiment. FIG. 6A schematically illustrates a plan view of a main part of the harmonic processing circuit. FIG. 6B B schematically illustrates a cross-sectional view of the main part of the harmonic processing circuit. The schematic cross-sectional view of FIG. 6B is taken along line VI-VI of FIG. 6A.

A harmonic processing circuit 200 depicted in FIGS. 6A and 6B is an example of the above harmonic processing circuit 40 and the like. The harmonic processing circuit 200 includes a conductor layer 210, a dielectric film 220, a dielectric film 230, a wire 240, and a wire 250.

Various conductor materials are used for the conductor layer 210. For example, the conductor layer 210 may include a conductor material containing one, two, or more selected from copper (Cu), aluminum (Al), silver (Ag), gold (Au), molybdenum (Mo), palladium (Pd), nickel (Ni), and platinum (Pt). The conductor layer 210 may have a single-layer structure of one type of conductor material or a laminated structure of one, two, or more types of conductor materials. For the conductor layer 210, any element or conductor material may be used as long as a certain level or more of thermal conductivity and electrical conductivity is obtained. For example, the conductor layer 210 may be formed by plating Au on the surface of a metal layer mainly composed of Cu. For example, the conductor layer 210 is set to a ground potential.

As illustrated in FIG. 6B, the dielectric film 220 is provided on a surface 210a of the conductor layer 210. The dielectric film 230 is provided on a surface 220a of the dielectric film 220 opposite to the conductor layer 210. Various dielectric materials are used for the dielectric films 220 and 230. For example, the dielectric films 220 and 230 are each made of a dielectric material containing one, two, or more selected from resin, silicon nitride (SiN), silicon oxide (SiO), aluminum nitride (AlN), aluminum oxide (AlO), aluminum silicate (AlSiO), aluminum oxynitride (AlON), and magnesium oxide (MgO). Each of the dielectric films 220 and 230 may have a single-layer structure of one type of dielectric material or a laminated structure of one, two, or more types of dielectric materials.

For the dielectric films 220 and 230, the same or different types of dielectric materials may be used. For example, the dielectric films 220 and 230 may be made of dielectric materials having the same or different relative permittivity values.

As illustrated in FIG. 6A, the wire 240 has a first end 241 connected to a transmission line 260 for transmitting the fundamental wave, and a second end 242 which is opened. That is, the wire 240 is an open stub. The transmission line 260 is an example of the transmission line 30 described in the first embodiment. The wire 240, the first end 241, and the second end 242 are examples of the wire 41, the first end 41a, and the second end 41b, respectively, described in the first embodiment. As illustrated in FIGS. 6A and 6B, the wire 240 and the transmission line 260 are provided on a surface 230a of the dielectric film 230 opposite to the dielectric film 220.

As illustrated in FIG. 6A, the wire 250 has both ends, that is, a first end 251 and a second end 252 being opened. The wire 250 is arranged parallel to and apart from the wire 240. The wire 250, the first end 251, and the second end 252 are examples of the wire 42, the first end 42a, and the second end 42b, respectively, described in the first embodiment. As illustrated in FIGS. 6A and 6B, the wire 250 is provided on a surface 220a of the dielectric film 220 opposite to the conductor layer 210, and is covered with the dielectric film 230.

As illustrated in FIGS. 6A and 6B, the wires 240 and 250 are provided so as to partially overlap each other in a plan view and a cross-sectional view. A capacitive coupling 270 (FIG. 6B) is realized by a part of the wire 240 and a part of the wire 250 which are provided to overlap each other and a portion 231 of the dielectric film 230 interposed therebetween. The portion 231 of the dielectric film 230 interposed between the wires 240 and 250 overlapping each other functions as the dielectric film 43 described in the first embodiment.

Various conductor materials are used for the wires 240 and 250. For example, each of the wires 240 and 250 may include a conductor material containing one, two, or more selected from Cu, Al, Ag, Au, Mo, Ni, Pt, titanium (Ti), and tungsten (W). The wires 240 and 250 may have a single-layer structure of one type of conductor material or a laminated structure of one, two, or more types of conductor materials. For each of the wires 240 and 250, any element or conductor material may be used as long as a certain level or more of thermal conductivity and electrical conductivity is obtained.

The harmonic processing circuit 200 is realized, for example, in the form of a microstrip line. As described in the first embodiment, the dimensions (length and width) of the wires 240 and 250 are set based on the fundamental wave and a harmonic to be shorted. The thickness of the dielectric film 230 interposed between the wires 240 and 250, that is, the interval of the overlapping part between the wires 240 and 250 is set based on the material (relative permittivity value) of the dielectric film 230. The thickness of the dielectric film 230 and the dielectric film 220 between the wire 240 and the conductor layer 210 and the thickness of the dielectric film 220 between the wire 250 and the conductor layer 210 are set based on the materials (relative permittivity values) of the dielectric films 230 and 220 as well as the characteristic impedance. In the harmonic processing circuit 200, the material of the conductor layer 210, the materials and dimensions of the dielectric films 220 and 230, and the materials and dimensions of the wires 240 and 250 are appropriately selected so that the harmonic of a short circuit target is shorted by the capacitive coupling 270.

In the harmonic processing circuit 200, the interval of the overlapping part between the wires 240 and 250 and the material (relative permittivity value) of the dielectric film 230 with the portion 231 thereof interposed between the wires 240 and 250 are appropriately selected. Accordingly, in the harmonic processing circuit 200, the capacitance value between the wires 240 and 250 is accurately adjusted to an appropriate value compared to a case where a gap (void space or air gap) is formed between the wires 240 and 250.

Note that the harmonic processing circuit 200 may be mounted on a different component by bonding the conductor layer 210 to the different component using a bonding material, such as solder or resin.

Further, in the harmonic processing circuit 200, a double-sided printed circuit board may be used for the laminated structure portion of the conductor layer 210, the dielectric film 220, and the wire 250. That is, the double-sided printed circuit board used in the harmonic processing circuit 200 may have a configuration in which the wire 250 is provided on the surface 220a of the dielectric film 220 made of resin or the like, and the conductor layer 210 is provided on the other surface of the dielectric film 220 opposite to the surface 220a. In the double-sided printed circuit board, the dielectric film 230 covering the wire 250 may be provided on the surface 220a of the dielectric film 220, and the wire 240 and the transmission line 260 may be provided on the surface 230a of the dielectric film 230. In the harmonic processing circuit 200, the conductor layer 210 may be provided on one surface of a single-sided or double-sided printed circuit board. The dielectric film 220 may be provided on the surface 210a of the conductor layer 210 placed on the printed circuit board, the wire 250 and the dielectric film 230 may be provided on the surface 220a of the dielectric film 220, and the wire 240 and the transmission line 260 may be provided on the surface 230a of the dielectric film 230.

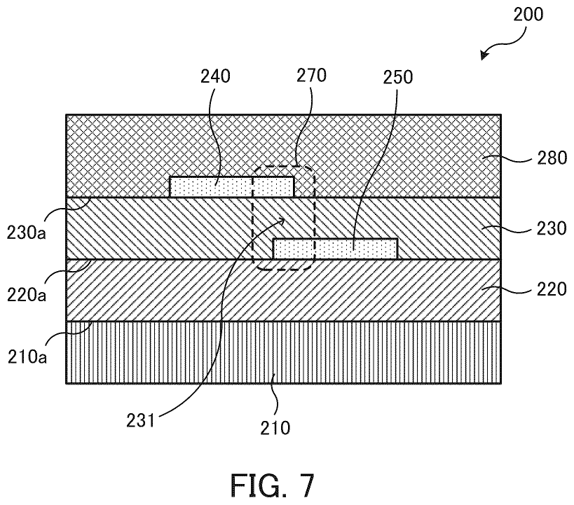

FIG. 7 further illustrates the first configuration example of the harmonic processing circuit according to the second embodiment. FIG. 7 schematically illustrates a cross-sectional view of a main part of another example of the harmonic processing circuit.

As illustrated in FIG. 7, a dielectric film 280 covering the wire 240 (and the transmission line 260) on the surface 230a may be further provided on the surface 230a of the dielectric film 230 of the harmonic processing circuit 200 illustrated in FIG. 6B. The dielectric film 280 is made of a dielectric material containing one, two, or more selected from Si-containing substances such as SiN, Al-containing substances such as AlN, Mg-containing substances such as MgO, and Ti-containing substances such as barium titanate (BaTiO₃). The dielectric film 280 may have a single-layer structure of one type of dielectric material or a laminated structure of one, two, or more types of dielectric materials. By further providing the dielectric film 280 that covers the wire 240 (and the transmission line 260), it is possible to prevent the electric field generated in the wire 240 (and the transmission line 260) from diverging to the outside.

Regarding the harmonic processing circuit 200 of the first configuration example, the wire 240 is also referred to as the “first wire”, the wire 250 is also referred to as the “second wire”, and the portion 231 of the dielectric film 230 interposed between the wires 240 and 250 is also referred to as the “first dielectric film”. The dielectric film 220 is also referred to as the “second dielectric film”, the dielectric film 230 is also referred to as the “third dielectric film”, and the dielectric film 280 is also referred to as the “fourth dielectric film”.

### Second Configuration Example

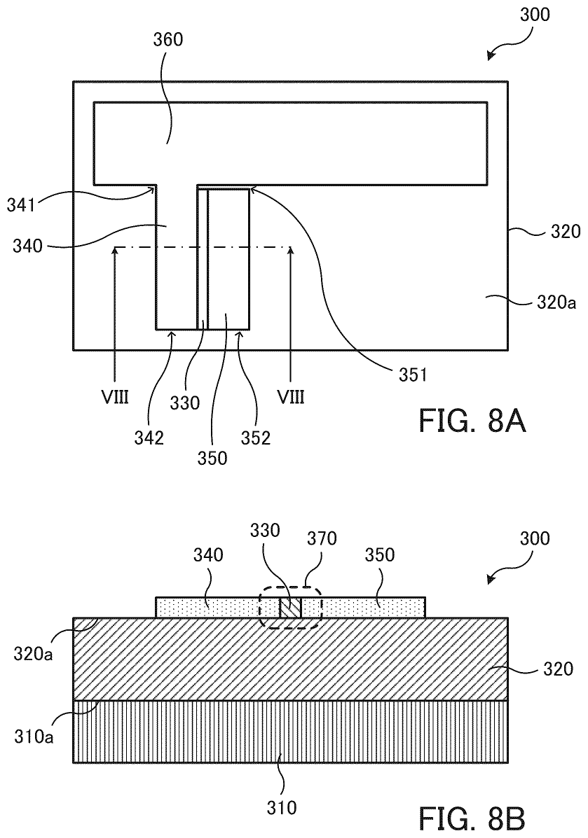

FIGS. 8A and 8B illustrate the second configuration example of the harmonic processing circuit according to the second embodiment. FIG. 8A schematically illustrates a plan view of a main part of the harmonic processing circuit. FIG. 8B schematically illustrates a cross-sectional view of the main part of the harmonic processing circuit. The schematic cross-sectional view of FIG. 8B is taken along line VIII-VIII of FIG. 8A.

A harmonic processing circuit 300 depicted in FIGS. 8A and 8B is an example of the above harmonic processing circuit 40 and the like. The harmonic processing circuit 300 includes a conductor layer 310, a dielectric film 320, a dielectric film 330, a wire 340, and a wire 350.

Various conductor materials are used for the conductor layer 310. For example, the conductor layer 310 may include a conductor material containing one, two, or more selected from Cu, Al, Ag, Au, Mo, Pd, Ni, and Pt. The conductor layer 310 may have a single-layer structure of one type of conductor material or a laminated structure of one, two, or more types of conductor materials. For the conductor layer 310, any element or conductor material may be used as long as a certain level or more of thermal conductivity and electrical conductivity is obtained. For example, the conductor layer 310 may be formed by plating Au on the surface of a metal layer mainly composed of Cu. For example, the conductor layer 310 is set to a ground potential.

As illustrated in FIG. 8B, the dielectric film 320 is provided on a surface 310a of the conductor layer 310. Various dielectric materials are used for the dielectric film 320. For example, the dielectric film 320 is made of a dielectric material containing one, two, or more selected from resin, SiN, Sio, AlN, AlO, AlSiO, ALON, and MgO. The dielectric film 320 may have a single-layer structure of one type of dielectric material or a laminated structure of one, two, or more types of dielectric materials.

As illustrated in FIG. 8A, the wire 340 has a first end 341 connected to a transmission line 360 for transmitting the fundamental wave, and a second end 342 which is opened. That is, the wire 340 is an open stub. The transmission line 360 is an example of the transmission line 30 described in the first embodiment. The wire 340, the first end 341, and the second end 342 are examples of the wire 41, the first end 41a, and the second end 41b, respectively, described in the first embodiment. As illustrated in FIGS. 8A and 8B, the wire 340 and the transmission line 360 are provided on a surface 320a of the dielectric film 320 opposite to the conductor layer 310.

As illustrated in FIG. 8A, the wire 350 has both ends, that is, a first end 351 and a second end 352 being opened. The wire 350 is arranged parallel to and apart from the wire 340. The wire 350, the first end 351, and the second end 352 are examples of the wire 42, the first end 42a, and the second end 42b, respectively, described in the first embodiment. As illustrated in FIGS. 8A and 8B, the wire 350 is provided together with the wire 340 on the surface 320a of the dielectric film 320 opposite to the conductor layer 310.

Various conductor materials are used for the wires 340 and 350. For example, each of the wires 340 and 350 may include a conductor material containing one, two, or more selected from Cu, Al, Ag, Au, Mo, Ni, Pt, Ti, and W. The wires 340 and 350 may have a single-layer structure of one type of conductor material or a laminated structure of one, two, or more types of conductor materials. For each of the wires 340 and 350, any element or conductor material may be used as long as a certain level or more of thermal conductivity and electrical conductivity is obtained.

As illustrated in FIGS. 8A and 8B, the dielectric film 330 is provided between the wires 340 and 350 on the surface 320a of the dielectric film 320. Various dielectric materials are used for the dielectric film 330. For example, the dielectric film 330 is made of a dielectric material containing one, two, or more selected from resin, SiN, Sio, AlN, Alo, AlSiO, AlON, and MgO. The dielectric film 330 may have a single-layer structure of one type of dielectric material or a laminated structure of one, two, or more types of dielectric materials. For the dielectric film 330, the same or different types of dielectric materials as the dielectric film 320 may be used. For example, the dielectric films 320 and 330 may be made of dielectric materials having the same or different relative permittivity values.

A capacitive coupling 370 (FIG. 8B) is realized by the wires 340 and 350 and the dielectric film 330 interposed therebetween. The dielectric film 330 functions as the dielectric film 43 described in the first embodiment.

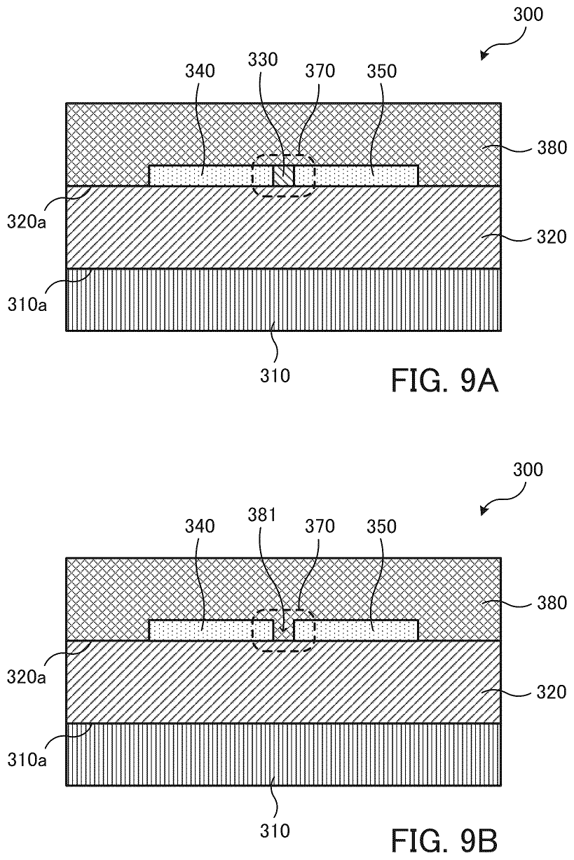

The harmonic processing circuit 300 is realized, for example, in the form of a microstrip line. As described in the first embodiment, the dimensions (length and width) of the wires 340 and 350 are set based on the fundamental wave and a harmonic to be shorted. The width of the dielectric film 330 interposed between the wires 340 and 350, that is, the interval between the wires 340 and 350 is set based on the material (relative permittivity value) of the dielectric film 330. The thickness of the dielectric film 320 between the wires 340 and 350 and the conductor layer 310 is set based on the material of the dielectric film 320 (relative permittivity value) and the characteristic impedance. In the harmonic processing circuit 300, the material of the conductor layer 310, the materials and dimensions of the dielectric films 320 and 330, and the materials and dimensions of the wires 340 and 350 are appropriately selected so that the harmonic of a short circuit target is shorted by the capacitive coupling 370. In the harmonic processing circuit 300, the interval between the wires 340 and 350 and the material (relative permittivity value) of the dielectric film 330 interposed between the wires 340 and 350 are appropriately selected. As will be described later (FIG. 9B), the material (relative permittivity value) of a dielectric film 380 with a portion 381 thereof interposed between the wires 340 and 350 is appropriately selected. Accordingly, in the harmonic processing circuit 300, the capacitance value between the wires 340 and 350 is accurately adjusted to an appropriate value compared to a case where a gap (void space or air gap) is formed between the wires 340 and 350.

Note that the harmonic processing circuit 300 may be mounted on a different component by bonding the conductor layer 310 to the different component using a bonding material, such as solder or resin.

Further, in the harmonic processing circuit 300, a double-sided printed circuit board may be used in which the wires 340 and 350 and the dielectric film 330 therebetween are provided on the surface 320a of the dielectric film 320 made of resin or the like, and the conductor layer 310 is provided on the other surface of the dielectric film 320 opposite to the surface 320a.

In the harmonic processing circuit 300, the conductor layer 310 may be provided on one surface of a single-sided or double-sided printed circuit board. The dielectric film 320 may be provided on the surface 310a of the conductor layer 310 placed on the printed circuit board, and the wires 340 and 350 and the dielectric film 330 may be provided on the surface 320a of the dielectric film 320.

FIGS. 9A and 9B further illustrate the second configuration example of the harmonic processing circuit according to the second embodiment. FIGS. 9A and 9B each schematically illustrate a cross-sectional view of a main part of yet another example of the harmonic processing circuit.

As illustrated in FIG. 9A, the dielectric film 380 covering the wires 340 and 350 and the dielectric film 330 (and the transmission line 360) on the surface 320a may be further provided on the surface 320a of the dielectric film 320 of the harmonic processing circuit 300 illustrated in FIG. 8B. The dielectric film 380 is made of a dielectric material containing one, two, or more selected from Si-containing substances such as SiN, Al-containing substances such as AlN, Mg-containing substances such as MgO, and Ti-containing substances such as BaTiO₃. The dielectric film 380 may have a single-layer structure of one type of dielectric material or a laminated structure of one, two, or more types of dielectric materials. By further providing the dielectric film 380 that covers the wires 340 and 350 and the dielectric film 330 (and the transmission line 360), it is possible to prevent the electric field generated in the wire 340 (and the transmission line 360) from diverging to the outside.

As illustrated in FIG. 9B, the dielectric film 380 covering the wires 340 and 350 (and the transmission line 360) may be further provided on the surface 320a of the dielectric film 320 on which the wires 340 and 350 (and the transmission line 360) are placed and the dielectric film 330 is omitted. In this case, the portion 381 of the dielectric film 380 provided between the wires 340 and 350 has the same function as that of the dielectric film 330. The capacitive coupling 370 is realized by the wires 340 and 350 and the portion 381 of the dielectric film 380 interposed therebetween.

Regarding the harmonic processing circuit 300 of the second configuration example, the wire 340 is also referred to as the “first wire”, the wire 350 is also referred to as the “second wire”, and the dielectric film 330 or the portion 381 of the dielectric film 380 interposed between the wires 340 and 350 is also referred to as the “first dielectric film”. The dielectric film 320 is also referred to as the “second dielectric film”, and the dielectric film 380 is also referred to as the “third dielectric film”.

### Third Configuration Example

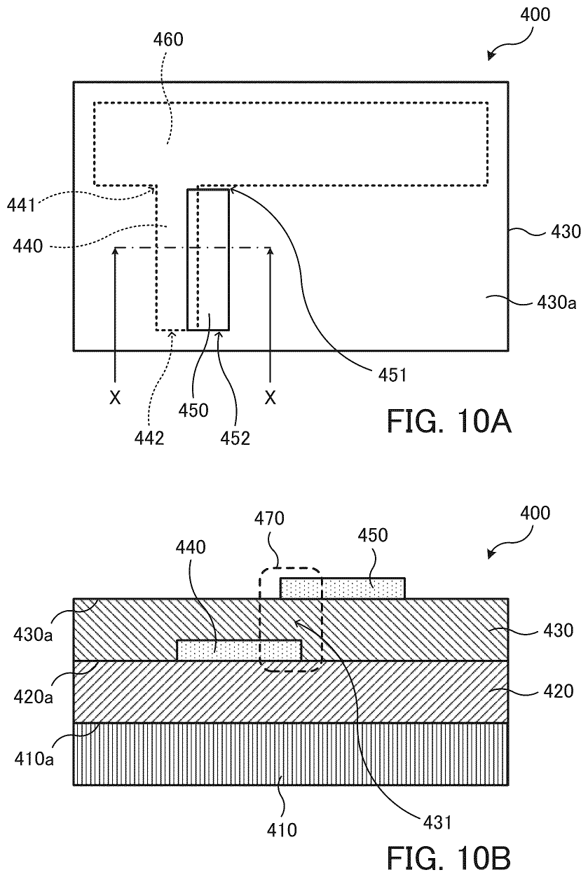

FIGS. 10A and 10B illustrate the third configuration example of the harmonic processing circuit according to the second embodiment. FIG. 10A schematically illustrates a plan view of a main part of the harmonic processing circuit. FIG. 10B schematically illustrates a cross-sectional view of the main part of the harmonic processing circuit. The schematic cross-sectional view of FIG. 10B is taken along line X-X of FIG. 10A.

A harmonic processing circuit 400 depicted in FIGS. 10A and 10B is an example of the above harmonic processing circuit 40 and the like. The harmonic processing circuit 400 includes a conductor layer 410, a dielectric film 420, a dielectric film 430, a wire 440, and a wire 450.

Various conductor materials are used for the conductor layer 410. For example, the conductor layer 410 may include a conductor material containing one, two, or more selected from Cu, Al, Ag, Au, Mo, Pd, Ni, and Pt. The conductor layer 410 may have a single-layer structure of one type of conductor material or a laminated structure of one, two, or more types of conductor materials. For the conductor layer 410, any element or conductor material may be used as long as a certain level or more of thermal conductivity and electrical conductivity is obtained. For example, the conductor layer 410 may be formed by plating Au on the surface of a metal layer mainly composed of Cu. For example, the conductor layer 410 is set to a ground potential.

As illustrated in FIG. 10B, the dielectric film 420 is provided on a surface 410a of the conductor layer 410. The dielectric film 430 is provided on a surface 420a of the dielectric film 420 opposite to the conductor layer 410.

Various dielectric materials are used for the dielectric films 420 and 430. For example, the dielectric films 420 and 430 are each made of a dielectric material containing one, two, or more selected from resin, SiN, Sio, AlN, AlO, AlSiO, AlON, and MgO. Each of the dielectric films 420 and 430 may have a single-layer structure of one type of dielectric material or a laminated structure of one, two, or more types of dielectric materials. For the dielectric films 420 and 430, the same or different types of dielectric materials may be used. For example, the dielectric films 420 and 430 may be made of dielectric materials having the same or different relative permittivity values.

As illustrated in FIG. 10A, the wire 440 has a first end 441 connected to a transmission line 460 for transmitting the fundamental wave, and a second end 442 which is opened. That is, the wire 440 is an open stub. The transmission line 460 is an example of the transmission line 30 described in the first embodiment. The wire 440, the first end 441, and the second end 442 are examples of the wire 41, the first end 41a, and the second end 41b, respectively, described in the first embodiment. As illustrated in FIGS. 10A and 10B, the wire 440 and the transmission line 460 are provided on the surface 420a of the dielectric film 420 opposite to the conductor layer 410, and are covered with the dielectric film 430.

As illustrated in FIG. 10A, the wire 450 has both ends, that is, a first end 451 and a second end 452 being opened. The wire 450 is arranged parallel to and apart from the wire 440. The wire 450, the first end 451, and the second end 452 are examples of the wire 42, the first end 42a, and the second end 42b, respectively, described in the first embodiment. As illustrated in FIGS. 10A and 10B, the wire 450 is provided on a surface 430a of the dielectric film 430 opposite to the dielectric film 420.

As illustrated in FIGS. 10A and 10B, the wires 440 and 450 are provided so as to partially overlap each other in a plan view and a cross-sectional view. A capacitive coupling 470 (FIG. 10B) is realized by a part of the wire 440 and a part of the wire 450 which are provided to overlap each other and a portion 431 of the dielectric film 430 interposed therebetween. The portion 431 of the dielectric film 430 interposed between the wires 440 and 450 overlapping each other functions as the dielectric film 43 described in the first embodiment.

Various conductor materials are used for the wires 440 and 450. For example, each of the wires 440 and 450 may include a conductor material containing one, two, or more selected from Cu, Al, Ag, Au, Mo, Ni, Pt, Ti, and W. The wires 440 and 450 may have a single-layer structure of one type of conductor material or a laminated structure of one, two, or more types of conductor materials. For each of the wires 440 and 450, any element or conductor material may be used as long as a certain level or more of thermal conductivity and electrical conductivity is obtained.

The harmonic processing circuit 400 is realized, for example, in the form of a microstrip line. As described in the first embodiment, the dimensions (length and width) of the wires 440 and 450 are set based on the fundamental wave and a harmonic to be shorted. The thickness of the dielectric film 430 interposed between the wires 440 and 450, that is, the interval of the overlapping part between the wires 440 and 450 is set based on the material (relative permittivity value) of the dielectric film 430. The thicknesses of the dielectric film 430 and the dielectric film 420 between the wire 450 and the conductor layer 410 and the thickness of the dielectric film 420 between the wire 440 and the conductor layer 410 are set based on the materials (relative permittivity values) of the dielectric films 430 and 420 as well as the characteristic impedance. In the harmonic processing circuit 400, the material of the conductor layer 410, the materials and dimensions of the dielectric films 420 and 430, and the materials and dimensions of the wires 440 and 450 are appropriately selected so that the harmonic of a short circuit target is shorted by the capacitive coupling 470.

In the harmonic processing circuit 400, the interval of the overlapping part between the wires 440 and 450 and the material (relative permittivity value) of the dielectric film 430 with the portion 431 thereof interposed between the wires 440 and 450 are appropriately selected. Accordingly, in the harmonic processing circuit 400, the capacitance value between the wires 440 and 450 is accurately adjusted to an appropriate value compared to a case where a gap (void space or air gap) is formed between the wires 440 and 450.

In the harmonic processing circuit 400, the wire 440 and the transmission line 460 are covered with the dielectric film 430. This prevents the electric field generated in the wire 440 and the transmission line 460 from diverging to the outside. Further, in the harmonic processing circuit 400, of the dielectric films 420 and 430, only one dielectric film 420 is provided between the wire 440 and the transmission line 460 and the conductor layer 410 in such a manner as to separate the wire 440 and the transmission line 460 from the conductor layer 410. Therefore, compared to the harmonic processing circuit 200 (FIGS. 6A and 6B), it is possible to reduce the distance of the wire 440 and the transmission line 460 from the conductor layer 410. This prevents the divergence of the electric field of the wire 440 and the transmission line 460 toward the conductor layer 410.

Note that the harmonic processing circuit 400 may be mounted on a different component by bonding the conductor layer 410 to the different component using a bonding material, such as solder or resin.

Further, in the harmonic processing circuit 400, a double-sided printed circuit board may be used for the laminated structure portion of the conductor layer 410, the dielectric film 420, the wire 440, and the transmission line 460. That is, the double-sided printed circuit board used in the harmonic processing circuit 400 may have a configuration in which the wire 440 and the transmission line 460 are provided on the surface 420a of the dielectric film 420 made of resin or the like, and the conductor layer 410 is provided on the other surface of the dielectric film 420 opposite to the surface 420a. In the double-sided printed circuit board, the dielectric film 430 covering the wire 440 and the transmission line 460 may be provided on the surface 420a of the dielectric film 420, and the wire 450 may be provided on the surface 430a of the dielectric film 430.

In the harmonic processing circuit 400, the conductor layer 410 may be provided on one surface of a single-sided or double-sided printed circuit board. The dielectric film 420 may be provided on the surface 410a of the conductor layer 410 placed on the printed circuit board, then the wire 440, the transmission line 460, and the dielectric film 430 may be provided on the surface 420a of the dielectric film 420, and the wire 450 may be provided on the surface 430a of the dielectric film 430.

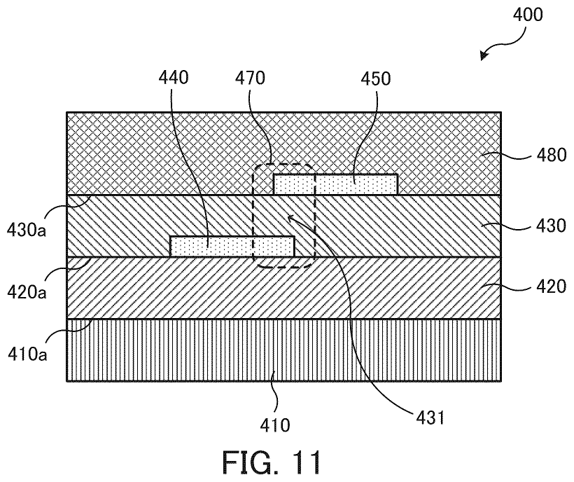

FIG. 11 further illustrates the third configuration example of the harmonic processing circuit according to the second embodiment. FIG. 11 schematically illustrates a cross-sectional view of a main part of yet another example of the harmonic processing circuit.

As illustrated in FIG. 11, a dielectric film 480 covering the wire 450 provided on the surface 430a may be further provided on the surface 430a of the dielectric film 430 of the harmonic processing circuit 400 illustrated in FIG. 10B. The dielectric film 480 is made of a dielectric material containing one, two, or more selected from Si-containing substances such as SiN, Al-containing substances such as AlN, Mg-containing substances such as MgO, and Ti-containing substances such as BaTio₃. The dielectric film 480 may have a single-layer structure of one type of dielectric material or a laminated structure of one, two, or more types of dielectric materials. By further providing the dielectric film 480 that covers the wire 450, it is possible to further prevent the electric field generated in the wire 440 and the transmission line 460 from diverging to the outside.

Regarding the harmonic processing circuit 400 of the third configuration example, the wire 440 is also referred to as the “first wire”, the wire 450 is also referred to as the “second wire”, and the portion 431 of the dielectric film 430 interposed between the wires 240 and 250 is also referred to as the “first dielectric film”. The dielectric film 420 is also referred to as the “second dielectric film”, the dielectric film 430 is also referred to as the “third dielectric film”, and the dielectric film 480 is also referred to as the “fourth dielectric film”.

### (c) Third Embodiment

Here, a configuration example of the amplifier 1 and the like is described as a third embodiment.

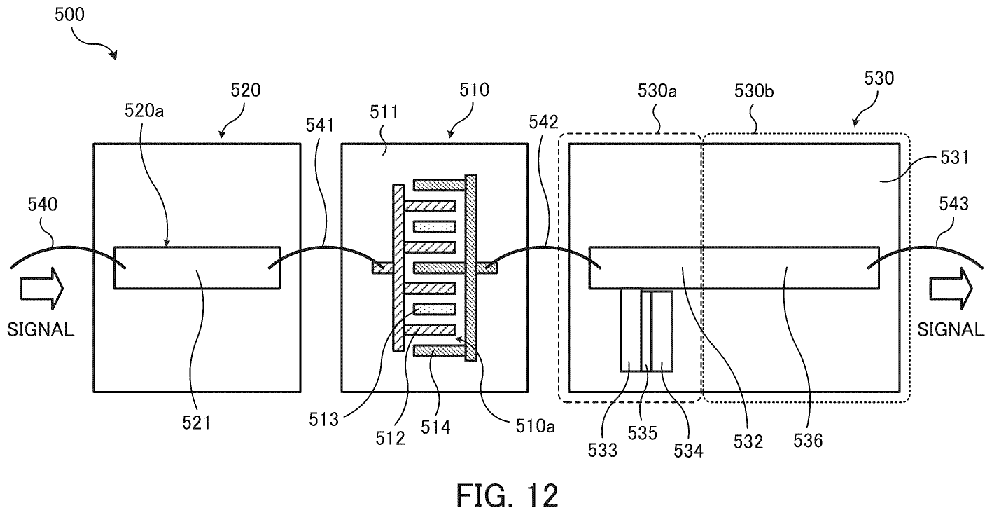

FIG. 12 illustrates a configuration example of an amplifier according to a third embodiment. FIG. 12 schematically illustrates a plan view of a main part of an example of the amplifier.

An amplifier 500 illustrated in FIG. 12 includes a semiconductor component 510, an input-side component 520, and an output-side component 530.

The semiconductor component 510 includes a substrate 511, a gate electrode 512, a source electrode 513, and a drain electrode 514.

For example, the substrate 511 includes a layer using a GaN-based nitride semiconductor. As an example, when the semiconductor component 510 includes a HEMT, the substrate 511 has a laminated structure of a nitride semiconductor which includes an electron transit layer using GaN or the like and an electron supply layer using AlGaN or the like having a larger band gap than GaN or the like. In this case, a two-dimensional electron gas (2DEG) region is generated in the electron transit layer stacked on the electron supply layer.

The gate electrode 512, the source electrode 513, and the drain electrode 514, each of which is made of a predetermined metal, are provided on the substrate 511. For example, each of the gate electrode 512 and the drain electrode 514 has a comb shape. For example, the source electrode 513 has island shapes. The source electrode 513 is drawn out to the back surface (the depth side of the paper surface) of the substrate 511 and grounded. The comb teeth of the gate electrode 512 are disposed between the pair of islands of the source electrode 513 and the comb teeth of the drain electrode 514. A transistor 510a, for example, a HEMT, is formed in a region where the comb teeth of the gate electrode 512 are provided together with the islands of the source electrode 513 and the comb teeth of the drain electrode 514 located on both sides of the comb teeth of the gate electrode 512.

The input-side component 520 is an example of a component including an input-side matching circuit 520a. The input-side matching circuit 520a includes a transmission line 521. A first end of the transmission line 521 is connected to a terminal (not illustrated) on a power supply side by a wire 540 or the like, and a second end is connected to the gate electrode 512 of the transistor 510a of the semiconductor component 510 by a wire 541 or the like. A signal is input from the power supply side to the gate electrode 512 of the transistor 510a through the transmission line 521. The input-side matching circuit 520a matches the impedance on the power supply side and the impedance on the input side of the transistor 510a to, for example, 50Ω or around 50 Ω.

The transmission line 521 of the input-side matching circuit 520a is schematically illustrated for convenience, and the shape thereof is not limited to that illustrated in FIG. 12. Various shapes capable of matching the impedance on the power supply side and the impedance on the input side of the transistor 510a may be adopted for the transmission line 521.

The output-side component 530 is an example of a component including a harmonic processing circuit 530a and an output-side matching circuit 530b. For example, the output-side component 530 is formed as one component in which the harmonic processing circuit 530a and the output-side matching circuit 530b are integrated. A case described here is that, for convenience, a sort of the harmonic processing circuit 300 (FIGS. 8A and 8B) of the second configuration example in the second embodiment is included as the harmonic processing circuit 530a.

The output-side component 530 includes a dielectric film 531 provided on a conductor layer (not illustrated). The harmonic processing circuit 530a includes a transmission line 532, a wire 533, a wire 534, and a dielectric film 535 provided on the dielectric film 531. A first end of the transmission line 532 is connected to the drain electrode 514 of the transistor 510a of the semiconductor component 510 by a wire 542 or the like. The wire 533 is an open stub having a first end connected to the transmission line 532. Both ends of the wire 534 are opened, and the wire 534 is arranged parallel to and apart from the wire 533. Both the wires 533 and 534 are set to have a length of ¼ wavelength of a harmonic to be shorted by the harmonic processing circuit 530a. The dielectric film 535 is provided between the wires 533 and 534.

The conductor layer and the dielectric film 531 provided thereon correspond to the conductor layer 310 and the dielectric film 320, respectively, of the harmonic processing circuit 300 (FIGS. 8A and 8B). The transmission line 532 corresponds to the transmission line 360 of the harmonic processing circuit 300 (FIGS. 8A and 8B). The wire 533 corresponds to the wire 340 of the harmonic processing circuit 300 (FIGS. 8A and 8B). The wire 534 corresponds to the wire 350 of the harmonic processing circuit 300 (FIGS. 8A and 8B). The dielectric film 535 corresponds to the dielectric film 330 of the harmonic processing circuit 300 (FIGS. 8A and 8B).

The harmonic processing circuit 530a shorts a predetermined harmonic of a signal output from the drain electrode 514 of the transistor 510a. The harmonic processing circuit 530a transmits the signal output from the drain electrode 514, with the predetermined harmonic shorted out, to the output-side matching circuit 530b.

The output-side matching circuit 530b includes a transmission line 536 provided on the dielectric film 531. The transmission line 536 of the output-side matching circuit 530b has a first end connected to the transmission line 532 of the harmonic processing circuit 530a and a second end connected to a load-side terminal (not illustrated) by a wire 543 or the like. For example, the transmission line 536 of the output-side matching circuit 530b is continuous with the transmission line 532 of the harmonic processing circuit 530a. The signal with the predetermined harmonic shorted is transmitted to the transmission line 536 of the output-side matching circuit 530b through the transmission line 532 of the harmonic processing circuit 530a. The output-side matching circuit 530b matches the impedance on the load side and the impedance on the output side of the transistor 510a including the harmonic processing circuit 530a to, for example, 50Ω or around 50 Ω.

The transmission line 536 of the output-side matching circuit 530b is schematically illustrated for convenience, and the shape thereof is not limited to that depicted in FIG. 12. For the transmission line 536, various shapes capable of matching the impedance on the load side and the impedance on the output side of the transistor 510a including the harmonic processing circuit 530a may be adopted.

A dielectric film (FIGS. 9A and 9B) covering the transmission line 532, the wires 533 and 534, and the dielectric film 535 of the harmonic processing circuit 530a and the transmission line 536 of the output-side matching circuit 530b may be further provided on the dielectric film 531 of the output-side component 530.

The function of the amplifier 1 illustrated in FIG. 2 is realized by the amplifier 500 having the configuration illustrated in FIG. 12.

FIG. 12 illustrates one component in which the harmonic processing circuit 530a and the output-side matching circuit 530b are integrated as the output-side component 530. Alternatively, a component including the harmonic processing circuit 530a and a component including the output-side matching circuit 530b may be prepared as separate components. In this case, the transmission line 532 of the component including the harmonic processing circuit 530a and the transmission line 536 of the component including the output-side matching circuit 530b are connected by a wire or the like.

FIG. 12 illustrates a case where a sort of the harmonic processing circuit 300 (FIGS. 8A and 8B) of the second configuration example described in the second embodiment is included as the harmonic processing circuit 530a. In addition, instead of the harmonic processing circuit 530a described as an example above, the harmonic processing circuit 200 (FIGS. 6A and 6B) of the first configuration example or the harmonic processing circuit 400 (FIGS. 10A and 10B) of the third configuration example described in the second embodiment may be used.

Instead of the harmonic processing circuit 530a described as an example above, a harmonic processing circuit having a configuration capable of shorting two or more harmonics may be used. The harmonic processing circuit may be integrated into one component together with the output-side matching circuit 530b, or may be prepared as a component separate from the component including the output-side matching circuit 530b. With such a configuration, for example, the function of the amplifier 1A as illustrated in FIG. 4 is realized.

A harmonic processing circuit for shorting one, two, or more harmonics may be used as the input-side component 520. The harmonic processing circuit is connected to a transmission line. A transmission line included in the harmonic processing circuit or the transmission line to which the harmonic processing circuit is connected has a first end connected to the transmission line 521 of the input-side matching circuit 520a and a second end connected to the gate electrode 512 of the transistor 510a by the wire 541 or the like. The harmonic processing circuit may be integrated into one component together with the input-side matching circuit 520a, or may be prepared as a component separate from the component including the input-side matching circuit 520a. With the above configuration, for example, the function of the amplifier 1B illustrated in FIG. 5 is realized.

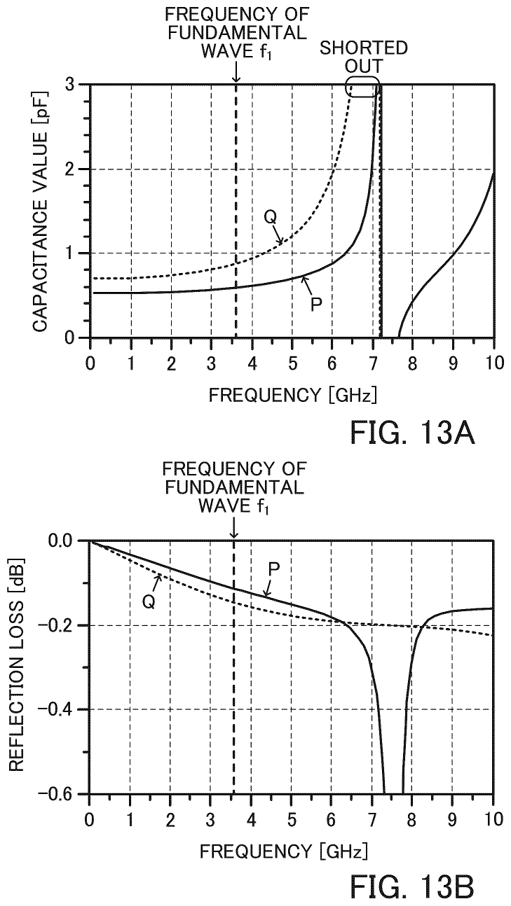

A FIGS. and 13B illustrate examples of simulation results of the amplifier according to the third embodiment. FIG. 13A illustrates an example of a simulation result of a capacitance value. FIG. 13B illustrates an example of a simulation result of the reflection loss (S11 loss or return loss).

Here, as a model of the simulation, a model of the amplifier 1 is used which has the configuration depicted in FIG. 2 and includes the harmonic processing circuit 300 (FIGS. 8A and 8B) of the second configuration example described in the second embodiment as the harmonic processing circuit 40. The model of the amplifier 1 is hereinafter also referred to as “model P” or simply “P”. The model P may be said to be a model of the amplifier 500 illustrated in FIG. 12.

As a simulation model for comparison, a model of the amplifier 100 is used which has the configuration depicted in FIG. 1 and includes the single open stub 141 as the harmonic processing circuit 140. The model of the amplifier 100 is hereinafter also referred to as “model Q” or simply “Q”.

In the simulation, the frequency f₁ of the fundamental wave is set to 3.6 GHz. Both of the harmonic processing circuit 40 (or the harmonic processing circuit 300) of the model P and the harmonic processing circuit 140 of the model Q are set to have dimensions for shorting the second harmonic with respect to the fundamental wave. That is, in the model Q, the length L₂ of the open stub 141 is set to ¼ wavelength of the second harmonic (λ₂/4), and the width W₀ thereof is set to 0.47 mm. In the model P, the wires 41 and 42 (or the wires 340 and 350) are set to the length L₂ of the ¼ wavelength of the second harmonic (λ₂/4), and the width W₂ thereof is set to 0.235 mm which is a half value of the width W₀ of the open stub 141.

As illustrated in FIG. 13A, in the model P and the model Q, the capacitance value diverges as the frequency approaches a frequency that is twice the frequency f₁ of the fundamental wave, and a tendency to cause a short circuit is observed. Here, from FIG. 13A, at the frequency f₁ of the fundamental wave, the capacitance value of the model P is 0.59 pF, whereas the capacitance value of the model Q is 0.87 pF. At the frequency f₁ of the fundamental wave, the capacitance value of the model P is smaller than the capacitance value of the model Q. As illustrated in FIG. 13A, in the model P, the frequency bandwidth is widened by the reduction of the capacitance value. Therefore, it is said that, in the amplifier 1 including the harmonic processing circuit 40 (or the harmonic processing circuit 300) like the model P, the stray capacitance is suppressed and a decrease in the frequency bandwidth due to the stray capacitance is prevented compared to the amplifier 100 including the harmonic processing circuit 140 like the model Q.

Further, from FIG. 13B, at the frequency f₁ of the fundamental wave, the reflection loss of the model P is −0.11 dB, whereas the reflection loss of the model Q is −0.15 dB. At the frequency f₁ of the fundamental wave, the reflection loss of the model P is reduced more than the reflection loss of the model Q. The reduction effect of the reflection loss of the model P with respect to the model Q corresponds to an improvement effect of 1% in terms of PAE. Therefore, in the amplifier 1 including the harmonic processing circuit 40 (or the harmonic processing circuit 300) like the model P, it is said that the reflection loss is suppressed and a decrease in the PAE due to the reflection loss is prevented compared to the amplifier 100 including the harmonic processing circuit 140 like the model Q.

According to the amplifier 1 including the harmonic processing circuit 40 (or the harmonic processing circuit 300), it is possible to suppress generation of stray capacitance associated with harmonic processing (shorting), and to suppress a reduction in the frequency bandwidth due to the stray capacitance and a decrease in the PAE caused by loss.

According to one aspect, it is possible to realize a high-performance harmonic processing circuit.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A harmonic processing circuit comprising:
a transmission line configured to transmit a fundamental wave;
a first wire configured to have a first end connected to the transmission line and a second end opened, a length between the first end and the second end being ¼ wavelength of a predetermined harmonic with respect to the fundamental wave;
a second wire configured to be parallel to and apart from the first wire, and have both ends opened, a length between the both ends being ¼ wavelength of the predetermined harmonic; and
a first dielectric film configured to be interposed between the first wire and the second wire.

2. The harmonic processing circuit according to claim 1, wherein the predetermined harmonic is a second harmonic.

3. The harmonic processing circuit according to claim 1, further comprising:
a conductor layer;
a second dielectric film configured to be on a first surface of the conductor layer; and
a third dielectric film configured to be on a second surface of the second dielectric film opposite to the conductor layer,
wherein:
the first wire is on a third surface of the third dielectric film opposite to the second dielectric film,
the second wire is on the second surface of the second dielectric film and is covered with the third dielectric film, and
the first dielectric film is a part of the third dielectric film.

4. The harmonic processing circuit according to claim 3, wherein different types of materials are used for the second dielectric film and the third dielectric film.

5. The harmonic processing circuit according to claim 3, wherein a same type of material is used for the second dielectric film and the third dielectric film.

6. The harmonic processing circuit according to claim 3, further comprising a fourth dielectric film configured to be on the third surface of the third dielectric film and cover the first wire.

7. The harmonic processing circuit according to claim 3, wherein the first wire and the second wire at least partially overlap each other in a plan view.

8. The harmonic processing circuit according to claim 1, further comprising:
a conductor layer; and
a second dielectric film configured to be on a first surface of the conductor layer;
wherein:
the first wire and the second wire are on a second surface of the second dielectric film opposite to the conductor layer, and
the first dielectric film is interposed between the first wire and the second wire on the second surface of the second dielectric film.

9. The harmonic processing circuit according to claim 8, wherein different types of materials are used for the first dielectric film and the second dielectric film.

10. The harmonic processing circuit according to claim 8, wherein a same type of material is used for the first dielectric film and the second dielectric film.

11. The harmonic processing circuit according to claim 8, further comprising a third dielectric film configured to be on the second surface of the second dielectric film and cover the first wire and the second wire.

12. The harmonic processing circuit according to claim 11, wherein the first dielectric film is a part of the third dielectric film.

13. The harmonic processing circuit according to claim 1, further comprising:
a conductor layer;
a second dielectric film configured to be on a first surface of the conductor layer; and
a third dielectric film configured to be on a second surface of the second dielectric film opposite to the conductor layer,
wherein:
the first wire is on the second surface of the second dielectric film and is covered by the third dielectric film,
the second wire is on a third surface of the third dielectric film opposite to the second dielectric film, and
the first dielectric film is a part of the third dielectric film.

14. The harmonic processing circuit according to claim 13, wherein different types of materials are used for the second dielectric film and the third dielectric film.

15. The harmonic processing circuit according to claim 13, wherein a same type of material is used for the second dielectric film and the third dielectric film.

16. The harmonic processing circuit according to claim 13, further comprising a fourth dielectric film configured to be on the third surface of the third dielectric film and cover the second wire.

17. The harmonic processing circuit according to claim 13, the first wire and the second wire at least partially overlap each other in a plan view.

18. An amplifier comprising:
a transistor; and
a harmonic processing circuit configured to be connected to the transistor,
wherein the harmonic processing circuit includes:
a transmission line which transmits a fundamental wave,
a first wire which has a first end connected to the transmission line and a second end opened, a length between the first end and the second end being ¼ wavelength of a predetermined harmonic with respect to the fundamental wave,
a second wire which is parallel to and apart from the first wire, and has both ends opened, a length between the both ends being ¼ wavelength of the predetermined harmonic, and
a first dielectric film which is interposed between the first wire and the second wire.
